(19) United States
(12) Patent Application Publication
(10) Pub. No.: US 2025/0386721 A1
(43) Pub. Date: Dec. 18, 2025

(54) METHOD FOR MANUFACTURING DISPLAY PANEL, AND DISPLAY PANEL

(71) Applicant: HKC CORPORATION LIMITED, SHENZHEN (CN)

(72) Inventors: Guoxing ZHOU, SHENZHEN (CN); Lidan YE, SHENZHEN (CN)

(73) Assignee: HKC CORPORATION LIMITED, SHENZHEN (CN)

(21) Appl. No.: 19/235,132

(22) Filed: Jun. 11, 2025

(30) Foreign Application Priority Data
Jun. 14, 2024 (CN) 202410773885.2

(51) Int. Cl. H10K 71/60; H10K 59/12; H10K 59/122; H10K 102/00

(52) U.S. Cl. CPC H10K 71/60; H10K 59/1201; H10K 59/122; H10K 2102/351

(57) ABSTRACT

A method for manufacturing a display panel and a display panel are provided. The method includes: providing an array substrate; covering the surface of the array substrate with an inorganic thin film; fabricating multiple conductive isolation structures on a surface of the inorganic thin film; removing the inorganic thin film between adjacent two of the multiple conductive isolation structures and exposing a corresponding one of pixel anodes on the surface of the array substrate; fabricating an auxiliary layer between the adjacent two of the multiple conductive isolation structures and at a position close to a corresponding one of conductive isolation structures; and sequentially depositing an organic light-emitting layer and a pixel cathode between the adjacent two of the multiple conductive isolation structures, such that the pixel cathode is connected to the cathode conductive layer of the corresponding one of conductive isolation structures through the auxiliary layer.

### CROSS REFERENCE TO RELATED APPLICATIONS

The present disclosure claims priority of Chinese Patent Application No. 202410773885.2, filed on Jun. 14, 2024, the entire contents of which are hereby incorporated by reference in their entireties.

### TECHNICAL FIELD

The present disclosure relates to the field of display technologies, and in particular to a method for manufacturing a display panel and a display panel.

### BACKGROUND

An organic light emitting diode (OLED) display panel has many advantages of an all-solid-state design, a self-emissive capability, high brightness, high contrast, an ultra-thin structure, low power consumption, an unrestricted viewing angle (i.e., a wide viewing angle), a wide operating temperature range, etc. Therefore, the OLED display panel has received increasing attention.

In the application of a mask-less process, an organic pixel defining layer may be changed to an inorganic thin film in an original plasma fluorination annealing (PFA) process, such that it may better block the invasion of water and oxygen. Therefore, an inorganic thin film process has been increasingly applied to fabricate a pixel defining layer.

Since the inorganic thin film is served as the pixel defining layer, it is difficult to control a dry etching angle, resulting in a problem that it is difficult to control an overlapping angle between the inorganic thin film and a pixel cathode and an overlapping height between the inorganic thin film and the pixel cathode. Therefore, it may further cause a problem of poor overlapping of the pixel cathode.

### SUMMARY OF THE DISCLOSURE

According to a first aspect, some embodiments of the present disclosure provide a method for manufacturing a display panel. The method for manufacturing the display panel includes: providing an array substrate, where a plurality of pixel anodes are arranged on a surface of the array substrate; covering the surface of the array substrate with an inorganic thin film; fabricating a plurality of conductive isolation structures on a surface of the inorganic thin film, where each of the plurality of conductive isolation structures includes a cathode conductive layer and a pixel isolation layer; removing the inorganic thin film between adjacent two of the plurality of conductive isolation structures and exposing a corresponding one of pixel anodes on the surface of the array substrate; fabricating an auxiliary layer between the adjacent two of the plurality of conductive isolation structures and at a position close to a corresponding one of conductive isolation structures; and sequentially depositing an organic light-emitting layer and a pixel cathode between the adjacent two of the plurality of conductive isolation structures, such that the pixel cathode is connected to the cathode conductive layer of the corresponding one of conductive isolation structures through the auxiliary layer.

According to a second aspect, some embodiments of the present disclosure provide a display panel. The display panel includes: an array substrate, a plurality of pixel anodes being formed on a surface of the array substrate; an inorganic pixel defining layer inorganic pixel defining layer, arranged on the surface of the array substrate and exposing the plurality of pixel anodes to form a pixel opening area; at least two conductive isolation structures, arranged on a surface of the inorganic pixel defining layer, where the conductive isolation structure includes a cathode conductive layer and a pixel isolation layer; an auxiliary layer, arranged between adjacent two of the at least two conductive isolation structures and at a position close to a corresponding one of conductive isolation structures; an organic light-emitting layer, covering a surface of the corresponding one of pixel anodes and a surface of the auxiliary layer; and a pixel cathode, covering a surface of the organic light-emitting layer and connected to the cathode conductive layer of the corresponding one of conductive isolation structures.

### BRIEF DESCRIPTION OF THE DRAWINGS

In order to more clearly describe the technical solutions in the embodiments of the present disclosure, the following will briefly introduce the drawings required in the description of the embodiments. Obviously, the drawings in the following description are only some embodiments of the present disclosure. For those skilled in the art, other drawings may be obtained based on these drawings without creative work.

FIG. 1 is a flow chart of a method for manufacturing a display panel according to some embodiments of the present disclosure.

FIG. 2 is a schematic structural diagram of the display panel according to some embodiments of the present disclosure.

FIG. 3 is a schematic structural diagram of the display panel according to some embodiments of the present disclosure.

FIG. 4 is a schematic structural diagram of the display panel according to some embodiments of the present disclosure.

FIG. 5 is a schematic structural diagram of a cathode conductive layer according to some embodiments of the present disclosure.

FIG. 6 is a schematic structural diagram of a cathode conductive layer according to some embodiments of the present disclosure.

### DETAILED DESCRIPTION

The following will be a clear and complete description of the technical solutions in the embodiments of the present disclosure in conjunction with the accompanying drawings in the embodiments of the present disclosure. Obviously, the described embodiments are only a part of the embodiments of the present disclosure, and not all of them. Based on the embodiments in the present disclosure, all other embodiments obtained by those skilled in the art without making creative labor fall within the scope of the present disclosure.

The terms used in the embodiments of the present disclosure are used solely for the purpose of describing particular embodiments and are not intended to limit the present disclosure. The singular forms of “a”, “said”, and “the” as used in the embodiments of the present disclosure and the appended claims are also intended to include plural form, unless clearly indicated. Terms “a plurality” generally include at least two, but does not exclude the inclusion of at least one.

It should be understood that the term “and/or” as used herein is simply a description of the association of related objects, indicating that three relationships can exist, e.g., A and/or B, which can mean: A alone, both A and B, and B alone. In addition, the character “/” in this document generally indicates that the before and after associated objects are in an “or” relationship. The terms “first”, “second”, and the like in the description, claims, and aforesaid drawings of the present disclosure are used to distinguish similar objects, rather than describing a particular sequence or order.

It is to be understood that the term “include”, “comprise”, or any other variant used herein is intended to cover non-exclusive inclusion, such that a process, method, article, or apparatus comprising a set of elements includes not only those elements, but also other elements not explicitly listed, or other elements that are not explicitly listed, or that are inherent to such process, method, article, or apparatus. Without further limitation, elements defined by the statement “including” do not preclude the existence of additional identical elements in the process, method, article, or apparatus that include the elements.

To be noted that, all directional indications (such as up, down, left, right, forward, backward . . . ) in the present disclosure are configured to explain relative positions between components at a particular pose (the pose shown in the accompanying drawings), movements, and so on. When the particular pose changes, the directional indications may change accordingly.

“Embodiment” herein means that a particular feature, structure, or characteristic described with reference to embodiments may be included in at least one embodiment of the present disclosure. The term appearing in various places in the specification are not necessarily as shown in the same embodiment, and are not exclusive or alternative embodiments that are mutually exclusive with other embodiments. Those skilled in the art will understand explicitly and implicitly that the embodiments described herein may be combined with other embodiments.

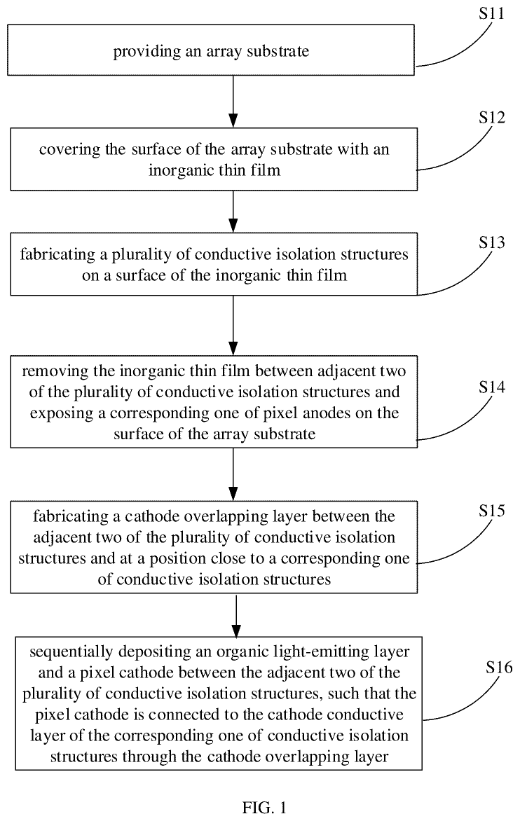

A method for manufacturing a display panel may be provided by some embodiments of the present disclosure. In some embodiments, as shown in FIG. 1, FIG. 1 is a flow chart of a method for manufacturing a display panel according to some embodiments of the present disclosure. As shown in FIG. 1, the method for manufacturing the display panel may include following operations.

In an operation at block S11, an array substrate may be provided.

A plurality of pixel anodes may be arranged at intervals and may be disposed on the surface of the array substrate. In some embodiments, a pixel circuit (also known as a thin-film transistor (TFT) circuit) may be further arranged inside the array substrate. The plurality of pixel anodes may be exposed on the surface of the array substrate. Each of the plurality of pixel anodes may be connected to the pixel circuit through a via hole, which is not limited herein.

In an operation at block S12, the surface of the array substrate may be covered by an inorganic thin film.

The inorganic thin film may include SiN, SiON, SiO, Al₂O₃, etc., which is not limited herein.

In some embodiments, the operation at block S12 may include: covering a surface of the each of the plurality of pixel anodes of the array substrate and a surface of a region between the plurality of pixel anodes with the inorganic thin film, i.e., covering an entire surface of the array substrate with the inorganic thin film. The surface of a corresponding one of pixel anodes may be covered by the inorganic thin film, such that it may be possible to prevent an anode from being damaged by an etching process during a subsequent operation of fabricating a cathode conductive layer and a pixel isolation layer. In addition, the inorganic thin film may be arranged between the plurality of pixel anodes and arranged on a surface of a part of the plurality of pixel anodes, such that it may be possible to facilitate forming an inorganic pixel defining layer (i.e., the inorganic pixel defining layer may be arranged in a non-display area of a pixel unit) during a subsequent operation. By replacing the organic pixel-defining layer with the inorganic thin film, it may be possible to block the invasion of water and oxygen, thereby protecting an organic light-emitting diode (OLED) pixel.

In an operation at block S13, a plurality of conductive isolation structures may be fabricated on a surface of the inorganic thin film.

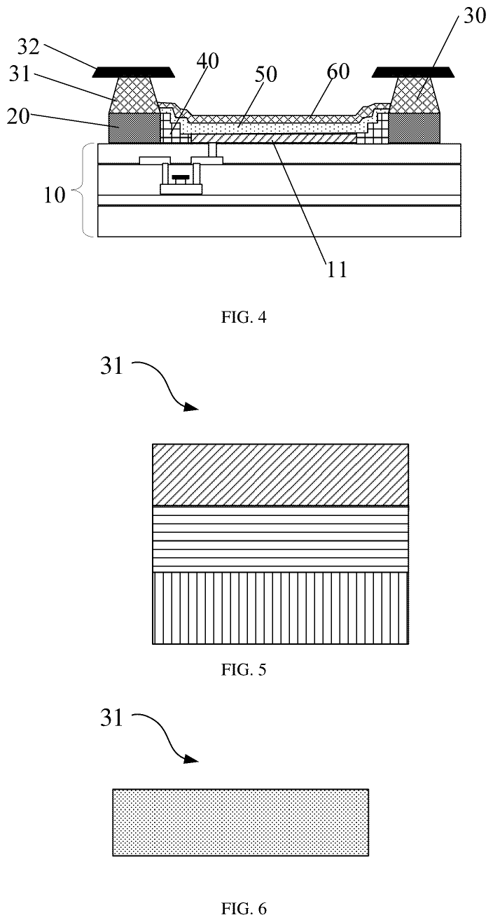

Each of the plurality of conductive isolation structures may include the cathode conductive layer and the pixel isolation layer. As shown in FIGS. 5-6, FIG. 5 is a schematic structural diagram of a cathode conductive layer according to some embodiments of the present disclosure. FIG. 6 is a schematic structural diagram of a cathode conductive layer according to some embodiments of the present disclosure. In some embodiments, the cathode conductive layer may be a metal laminated structure (as shown in FIG. 5) or a single-layer metal layer (as shown in FIG. 6). The cathode conductive layer may be configured to connect pixel cathodes of two adjacent sub-pixels, so as to connect the pixel cathodes of the entire display panel. In some embodiments, the cathode conductive layer may include a metal laminated structure formed by at least two of metal layers of Ti, Al, and Mo (not limited thereto). The single-layer metal layer includes one of the metal layers of Ti, Al, and Mo. The cathode conductive layer may have good electrical conductivity. The pixel isolation layer may be made of an inorganic thin film, a metal, or an organic per-fluoroalkoxy (PFA) material.

In some embodiments, the operation at block S13 may include: sequentially fabricating the cathode conductive layer and the pixel isolation layer on the surface of the inorganic thin film between adjacent two of the plurality of pixel anodes and obtaining a corresponding one of conductive isolation structures. That is, the corresponding one of conductive isolation structures may be fabricated on the surface of the inorganic thin film disposed between adjacent two of the plurality of pixel anodes.

In some embodiments, the operation at block S13 may include: fabricating the cathode conductive layer on an entire surface of the inorganic thin film, etching off/removing the cathode conductive layer in a pixel opening area (such as the cathode conductive layer disposed on a surface of at least part of the plurality of pixel anodes) by an etching process, fabricating the pixel isolation layer on a surface of the cathode conductive layer, etching off the pixel isolation layer at the pixel opening area (such as the cathode conductive layer disposed on the surface of at least part of the plurality of pixel anodes) by the etching process, and obtaining the corresponding one of conductive isolation structures, where the corresponding one of conductive isolation structures includes the cathode conductive layer and the pixel isolation layer. The pixel isolation layer may be disposed at a side of the cathode conductive layer away from the array substrate. An area of the pixel isolation layer in a direction approximately parallel to a plane of the array substrate may be greater than an area of the cathode conductive layer, such that an eaves-like structure may be formed. Therefore, it may be possible to facilitate the evaporation of the organic light-emitting layer and the pixel cathode at the pixel opening area.

In an operation at block S14, the inorganic thin film between adjacent two of the plurality of conductive isolation structures may be removed, and the corresponding one of pixel anodes on the surface of the array substrate may be exposed.

In some embodiments, the operation at block S14 may include: removing the inorganic thin film disposed on the surface of at least part of the plurality of pixel anodes by a dry etching process, and exposing the at least part of the plurality of pixel anodes.

In some embodiments, all of inorganic thin films between the adjacent two of the plurality of conductive isolation structures may be removed, and only the inorganic thin film disposed under the corresponding one of conductive isolation structures may be retained. In some embodiments, a part of the array substrate between the corresponding one of pixel anodes and the inorganic thin film may also be exposed.

In some embodiments, the inorganic thin film disposed on a surface of a part of the pixel anodes between the adjacent two of the plurality of conductive isolation structures may further be removed, which is not limited herein.

In the embodiments, there may be a height difference between the cathode conductive layer of the conductive isolation structure and the corresponding one of pixel anodes. The height difference may be formed by the inorganic thin film layer. In some embodiments, a height (i.e., a thickness) of the inorganic thin film may be greater than 0.5 μm. In some embodiments, a height (i.e., a thickness) of the cathode conductive layer may be greater than 1 μm. In some embodiments, a height (i.e., a thickness) of the pixel isolation layer may be in a range from 0.1 μm to 0.5 μm.

In an operation at block S15, an auxiliary layer or a filling layer may be fabricated between the adjacent two of the plurality of conductive isolation structures and at a position close to the corresponding one of conductive isolation structures.

In some embodiments, the operation at block S15 may include: fabricating the auxiliary layer at a position between the corresponding one of pixel anodes and the corresponding one of conductive isolation structures, and reducing the height difference between the cathode conductive layer of the corresponding one of conductive isolation structures and the corresponding one of pixel anodes.

In some embodiments, when the corresponding one of pixel anodes and the inorganic thin film are arranged at intervals, that is, when a part of the array substrate between the corresponding one of pixel anodes and the inorganic thin film is exposed, the operation at block S15 may include: fabricating the auxiliary layer on the surface of the array substrate between the corresponding one of pixel anodes and the corresponding one of conductive isolation structures.

In some embodiments, in a case where the surface of the part of the pixel anodes may be covered by the inorganic thin film and the part of the pixel anodes may be exposed, the operation at block S15 may include: fabricating the auxiliary layer on the surface of the corresponding one of pixel anodes close to the corresponding one of conductive isolation structures. That is, the auxiliary layer may be fabricated on the surface of the part of the pixel anodes, and it may be possible to ensure that the part of the pixel anodes may be still exposed, such that an anode of a pixel light-emitting area may be formed.

A height of the auxiliary layer may be not less than a thickness of the inorganic thin film, and the height of the auxiliary layer may be not more than a sum of the thicknesses of the inorganic thin film and a thickness of the cathode conductive layer. In this way, it may be possible to ensure that the pixel cathode subsequently arranged on a surface of the auxiliary layer may be overlapped with the cathode conductive layer, i.e., the pixel cathode may be connected to the cathode conductive layer. A sum of a thicknesses of the organic light-emitting layer and a thicknesses of the pixel cathode may be less than the thickness of the auxiliary layer. In some embodiments, the thickness of the cathode conductive layer may be greater than 1 μm. In some embodiments, a height of the auxiliary layer on a side close to the corresponding one of conductive isolation structures may be not less than the thickness of the inorganic thin film, and may be less than the sum of the thicknesses of the inorganic thin film and the thicknesses of the cathode conductive layer. A height of the auxiliary layer on a side away from the corresponding one of conductive isolation structures may be less than the thickness of the inorganic thin film.

The height of the auxiliary layer on the side close to the corresponding one of conductive isolation structures may be greater than the height of the auxiliary layer on the side away from the corresponding one of conductive isolation structures (i.e., the height of the auxiliary layer on a side close to the corresponding one of pixel anodes).

In some embodiments, the auxiliary layer includes an inclined surface inclined from the corresponding one of pixel anodes towards the cathode conductive layer. That is, the auxiliary layer may be an inclined-surface structure or a right-angled trapezoid structure, i.e., a cross-sectional shape of the auxiliary layer may be inclined/sloped or right-angled trapezoid. A surface of the auxiliary layer may be an inclined surface. In some embodiments, an inclination angle of the inclined surface of the auxiliary layer may be in a range from 10° to 45°, such that it may be possible to effectively solve a problem of poor overlapping between the pixel cathode and the cathode conductive layer due to a thin evaporation material and a weak climbing capacity for the subsequent inorganic material for thin-film packaging. In this way, it may be possible to ensure that the overlapping between the pixel cathode and the cathode conductive layer is not affected, and there will not be a case that cracking occurs during packaging.

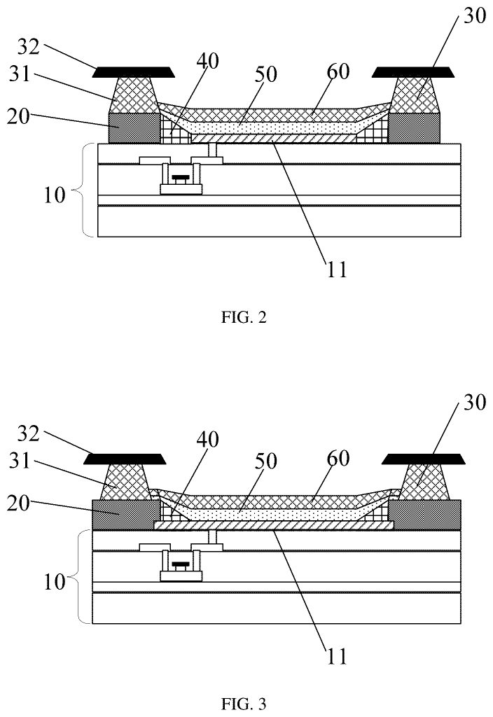

In some embodiments, the auxiliary layer may also be a stepped structure. The stepped structure may include a one-step stepped structure, a two-step stepped structure, or a multi-step stepped structure, which is not limited herein. When the auxiliary layer includes the one-step stepped structure, the height of the auxiliary layer on the side close to the corresponding one of conductive isolation structures may be equal to the height of the auxiliary layer on the side away from the corresponding one of conductive isolation structures, and the height of the auxiliary layer may be within a thickness range of the inorganic thin film, that is, the height of the auxiliary layer may be not greater than the thickness of the inorganic thin film. In this way, the height of the pixel cathode may be appropriately raised/elevated, such that it may be possible to reduce the height difference between the pixel cathode and the cathode conductive layer. In some embodiments, the height of the auxiliary layer may be half of the thickness of the inorganic thin film. When the auxiliary layer includes the two-step stepped structure or the multi-step stepped structure, the height of steps of the auxiliary layer on the side close to the corresponding one of conductive isolation structures may be successively greater than the height of steps of the auxiliary layer on the side away from the corresponding one of conductive isolation structures. That is, as shown in FIGS. 2-4, a step of the auxiliary layer at the side close to the corresponding one of conductive isolation structures may be higher than a corresponding step of the auxiliary layer at the side away from the corresponding one of conductive isolation structures. In some embodiments, the height of the auxiliary layer on the side close to the corresponding one of conductive isolation structures may be equal to or slightly greater than the thickness of the inorganic thin film.

In some embodiments, the height of the auxiliary layer may be in a range from 0.5 μm to 2 μm. The sum of the thicknesses of the inorganic thin film and the thicknesses of the cathode conductive layer may be greater than 2 μm, which is not limited herein.

In some embodiments, the operation at block S15 may include: coating a cathode overlapping material at a position close to the conductive isolation structure by a yellow-light coating process, where a coating area of the cathode overlapping material may be less than an area of the pixel, gradually etching or etching step by step the cathode overlapping material, and forming the auxiliary layer (also known as a cathode overlapping structure). In some embodiments, since auxiliary layers need to be arranged on both sides of the sub-pixel, the area of the auxiliary layer may be less than half of the area of the pixel.

In an operation at block S16: sequentially depositing an organic light-emitting layer and a pixel cathode between the adjacent two of the plurality of conductive isolation structures, such that the pixel cathode is connected to the cathode conductive layer of the corresponding one of conductive isolation structures through the auxiliary layer.

In some embodiments, the operation at block S16 may include: sequentially depositing the organic light-emitting layer and the pixel cathode on the surface of the corresponding one of pixel anodes and the surface of the auxiliary layer. The organic light-emitting layer and the pixel cathode may cover the surface of the corresponding one of pixel anodes at the pixel opening area and the surface of the auxiliary layer. In addition, the organic light-emitting layer and the pixel cathode may even cover a surface of the partially unetched inorganic thin film, which is not limited herein.

The organic light-emitting layer may be located between the pixel anode and the pixel cathode.

In the embodiments, the height of the pixel cathode may be raised through the auxiliary layer, such that it may be possible to improve the overlapping reliability between the cathode conductive layer of the corresponding one of conductive isolation structures and the corresponding one of pixel cathodes. Therefore, it may be possible to solve the problem of poor overlapping of the pixel cathode.

A display panel may be provided by some embodiments of the present disclosure. In some embodiments, as shown in FIG. 2, FIG. 2 is a schematic structural diagram of the display panel according to some embodiments of the present disclosure. As shown in FIG. 2, the display panel may include an array substrate 10. A plurality of pixel anodes 11 may be formed on a surface of the array substrate 10.

In some embodiments, the display panel may further include an inorganic pixel defining layer 20, and the inorganic pixel defining layer 20 may be arranged on a surface of the array substrate 10 and expose the plurality of pixel anodes 11 to form a pixel opening. In some embodiments, the inorganic pixel defining layer 20 may expose the plurality of pixel anodes 11. Alternatively, the inorganic pixel defining layer 20 may expose a part of the plurality of pixel anodes 11. The inorganic pixel defining layer 20 may be formed by the inorganic thin film in the method embodiments described above.

In some embodiments, the display panel may further include a conductive isolation structure 30, and the conductive isolation structure 30 may be arranged on a surface of the inorganic pixel defining layer 20. The conductive isolation structure 30 may include a cathode conductive layer 31 and a pixel isolation layer 32. In some embodiments, the number of the conductive isolation structures 30 may be multiple, such as at least two.

In some embodiments, the display panel may further include an auxiliary layer 40, and the auxiliary layer 40 may be arranged between adjacent two of the multiple conductive isolation structures 30 and at a position close to a corresponding one of conductive isolation structures 30. In some embodiments, when the inorganic pixel defining layer 20 and a corresponding one of pixel anodes 11 are arranged at intervals, and a part of the array substrate 10 is exposed, the auxiliary layer 40 is arranged on a surface of the part of array substrate 10 disposed between the corresponding one of conductive isolation structures 30 and the corresponding one of pixel anodes 11. An area of the auxiliary layer 40 may be less than an area of the pixel opening. The pixel opening may be referred to an opening on the surface of the part of array substrate 10 exposed by the inorganic pixel defining layer 20. The pixel opening may be configured to expose all the pixel anodes 11 or a part of the plurality of pixel anodes 11, the part of the array substrate 10, etc., which is not limited herein.

In some embodiments, the display panel may further include an organic light-emitting layer 50. The organic light-emitting layer 50 may cover a surface of the pixel anodes 11 disposed between adjacent two of the multiple conductive isolation structures 30 and a surface of the auxiliary layer 40.

In some embodiments, the display panel may further include a pixel cathode 60. The pixel cathode 60 may cover a surface of the organic light-emitting layer 50. The pixel cathode 60 may be connected to the cathode conductive layer 31 of the corresponding one of conductive isolation structures 30.

In the embodiments, a height of the auxiliary layer 40 at a position close to the corresponding one of conductive isolation structures 30 may be not less than a thickness of the inorganic pixel defining layer 20. In addition, the height of the auxiliary layer 40 at the position close to the corresponding one of conductive isolation structures 30 may be not more than a sum of the thicknesses of the inorganic pixel defining layer 20 and a thickness of the cathode conductive layer 31.

In the embodiments, a height of the auxiliary layer 40 on a side close to the corresponding one of conductive isolation structures 30 may be greater than a height of the auxiliary layer 40 on a side close to the corresponding one of pixel anodes 11, such that an inclined surface, which is inclined from the corresponding one of pixel anodes 11 towards the cathode conductive layer 31, may be formed. In the embodiments, an inclination angle of the inclined surface may be in a range from 10° to 45°, such that it may be possible to prevent the excessive steepness of the inclined surface, thereby reducing the climbing difficulty for the pixel cathode 60. In this way, it may be possible to improve the reliability of the overlapping between the pixel cathodes 60, so as to solve the problem of poor overlapping between the pixel cathodes.

In the embodiments, the auxiliary layer 40 may be arranged on the surface of the array substrate 10 between the corresponding one of conductive isolation structures 30 and the corresponding one of pixel anodes 11.

Further, as shown in FIG. 3, FIG. 3 is a schematic structural diagram of the display panel according to some embodiments of the present disclosure. As shown in FIG. 3, the inorganic pixel defining layer 20 may cover a surface of a part of the pixel anodes 11. The auxiliary layer 40 may be arranged on a part of the surface of the corresponding one of pixel anodes 11 close to the corresponding one of conductive isolation structures 30. A height of the auxiliary layer 40 at a position close to the corresponding one of conductive isolation structures 30 may be not less than the thickness of the inorganic pixel defining layer 20, and may be not more than a sum of the thicknesses of the inorganic pixel defining layer 20 and the thicknesses of the cathode conductive layer 31. In some embodiments, the height of the auxiliary layer 40 at the position close to the conductive isolation structure 30 may be equal to the thickness of the inorganic pixel defining layer 20. In some embodiments, the auxiliary layer 40 may be a right-angled triangle including an inclined surface, which is not limited herein.

In some embodiments, as shown in FIG. 4, FIG. 4 is a schematic structural diagram of the display panel according to some embodiments of the present disclosure. As shown in FIG. 4, the auxiliary layer 40 may also be a stepped structure, the stepped structure may include a one-step stepped structure, a two-step stepped structure, a multi-step stepped structure, etc., which is not limited herein. A step of the auxiliary layer 40 close to the corresponding one of conductive isolation structures 30 may be higher than a step of the auxiliary layer 40 away from the corresponding one of conductive isolation structures 30, such that it may be possible to reduce a direct climbing height of the pixel cathode 60.

The technical effect of the embodiments of the present disclosure may be as follows. By arranging an auxiliary layer between the conductive isolation structure and the pixel anode, the height difference between the pixel anode and the cathode conductive layer may be reduced through the auxiliary layer. In this way, it may be possible to facilitates the overlapping between the pixel cathode subsequently fabricated on the surface of the pixel anode and the cathode conductive layer, so as to solve the problem of poor overlapping between the cathodes.

The above description shows only embodiments of the present disclosure and does not limit the scope of the present disclosure. Any equivalent structure or equivalent process transformation performed based on the specification and accompanying drawings, applied directly or indirectly in other related fields, shall be equally covered by the scope of the present disclosure.

1. A method for manufacturing a display panel, comprising:
providing an array substrate, wherein a plurality of pixel anodes are arranged on a surface of the array substrate;
covering the surface of the array substrate with an inorganic thin film;
fabricating a plurality of conductive isolation structures on a surface of the inorganic thin film, wherein each of the plurality of conductive isolation structures comprises a cathode conductive layer and a pixel isolation layer;
removing the inorganic thin film between adjacent two of the plurality of conductive isolation structures and exposing a corresponding one of pixel anodes on the surface of the array substrate;
fabricating an auxiliary layer between the adjacent two of the plurality of conductive isolation structures and at a position close to a corresponding one of conductive isolation structures; and
sequentially depositing an organic light-emitting layer and a pixel cathode between the adjacent two of the plurality of conductive isolation structures, such that the pixel cathode is connected to the cathode conductive layer of the corresponding one of conductive isolation structures through the auxiliary layer.

2. The method for manufacturing the display panel according to claim 1, wherein fabricating the plurality of conductive isolation structures on the surface of the inorganic thin film, comprises:
sequentially fabricating the cathode conductive layer and the pixel isolation layer on the surface of the inorganic thin film between adjacent two of the plurality of pixel anodes and obtaining the corresponding one of conductive isolation structures;
wherein the pixel isolation layer is disposed at a side of the cathode conductive layer away from the array substrate, and an area of the pixel isolation layer in a direction parallel to a plane of the array substrate is greater than an area of the cathode conductive layer.

3. The method for manufacturing the display panel according to claim 1, wherein the inorganic thin film comprises at least one of SiN, SiON, SiO, and Al₂O₃.

4. The method for manufacturing the display panel according to claim 2, wherein the cathode conductive layer comprises a metal laminated structure, and the metal laminated structure comprises at least two of metal layers of Ti, Al, and Mo; or
the cathode conductive layer comprises a single-layer metal layer, and the single-layer metal layer comprises one of metal layers of Ti, Al, and Mo.

5. The method for manufacturing the display panel according to claim 2, wherein removing the inorganic thin film between the adjacent two of the plurality of conductive isolation structures, comprises:
removing the inorganic thin film disposed on the surface of at least part of the plurality of pixel anodes by a dry etching process, and exposing the corresponding one of pixel anodes;
wherein there is a height difference between the cathode conductive layer of the corresponding one of conductive isolation structures and the corresponding one of pixel anodes.

6. The method for manufacturing the display panel according to claim 5, wherein fabricating the auxiliary layer between the adjacent two of the plurality of conductive isolation structures and at the position close to the corresponding one of conductive isolation structures, comprises:
fabricating the auxiliary layer at a position between the corresponding one of pixel anodes and the corresponding one of conductive isolation structures;
wherein a height of the auxiliary layer is not less than a thickness of the inorganic thin film, and the height of the auxiliary layer is not more than a sum of the thicknesses of the inorganic thin film and a thickness of the cathode conductive layer.

7. The method for manufacturing the display panel according to claim 6, wherein a height of the auxiliary layer on a side close to the corresponding one of conductive isolation structures is greater than a height of the auxiliary layer on a side close to the corresponding one of pixel anodes, and an inclined surface inclined from the corresponding one of pixel anodes towards the cathode conductive layer is formed; and
an inclination angle of the inclined surface of the auxiliary layer is in a range from 10° to 45°.

8. The method for manufacturing the display panel according to claim 1, wherein covering the surface of the array substrate with the inorganic thin film, comprises:
covering a surface of each of the plurality of pixel anodes of the array substrate and a surface of a region between the plurality of pixel anodes with the inorganic thin film.

9. The method for manufacturing the display panel according to claim 1, wherein fabricating the auxiliary layer between the adjacent two of the plurality of conductive isolation structures and at the position close to the corresponding one of conductive isolation structures, comprises:
coating a cathode overlapping material at a position close to the conductive isolation structure by a yellow-light coating process, wherein a coating area of the cathode overlapping material is less than an area of a pixel; and
gradually etching the cathode overlapping material, and forming the auxiliary layer.

10. The method for manufacturing the display panel according to claim 1, wherein an area of the auxiliary layer is less than half of an area of a pixel.

11. The method for manufacturing the display panel according to claim 1, wherein fabricating the plurality of conductive isolation structures on the surface of the inorganic thin film, comprises:
fabricating the cathode conductive layer on an entire surface of the inorganic thin film;
etching off the cathode conductive layer disposed on a surface of at least part of the plurality of pixel anodes by an etching process;
fabricating the pixel isolation layer on a surface of the cathode conductive layer;
etching off the pixel isolation layer disposed on the surface of at least part of the plurality of pixel anodes by the etching process; and
obtaining the corresponding one of conductive isolation structures.

12. The method for manufacturing the display panel according to claim 1, wherein a height of the auxiliary layer on a side close to a corresponding one of conductive isolation structures is not less than a thickness of the inorganic thin film, and is less than a sum of the thicknesses of the inorganic thin film and a thicknesses of the cathode conductive layer; and
the height of the auxiliary layer on a side away from a corresponding one of conductive isolation structures is less than the thickness of the inorganic thin film.

13. A display panel, comprising:
an array substrate, a plurality of pixel anodes being formed on a surface of the array substrate;
an inorganic pixel defining layer inorganic pixel defining layer, arranged on the surface of the array substrate and exposing the plurality of pixel anodes to form a pixel opening area;
at least two conductive isolation structures, arranged on a surface of the inorganic pixel defining layer, wherein the conductive isolation structure comprises a cathode conductive layer and a pixel isolation layer;
an auxiliary layer, arranged between adjacent two of the at least two conductive isolation structures and at a position close to a corresponding one of conductive isolation structures;
an organic light-emitting layer, covering a surface of the corresponding one of pixel anodes and a surface of the auxiliary layer; and
a pixel cathode, covering a surface of the organic light-emitting layer and connected to the cathode conductive layer of the corresponding one of conductive isolation structures.

14. The display panel according to claim 13, wherein a height of the auxiliary layer on a side close to the corresponding one of conductive isolation structures is not less than a thickness of the inorganic pixel defining layer, and the height of the auxiliary layer on the side close to the corresponding one of conductive isolation structures is not more than a sum of the thicknesses of the inorganic pixel defining layer and a thickness of the cathode conductive layer.

15. The display panel according to claim 14, wherein the height of the auxiliary layer on the side close to the corresponding one of conductive isolation structures is greater than a height of the auxiliary layer on a side close to the corresponding one of pixel anodes, and an inclined surface inclined from the corresponding one of pixel anodes towards the cathode conductive layer is formed; and
an inclination angle of the inclined surface of the auxiliary layer is in a range from 10° to 45°.

16. The display panel according to claim 13, wherein the auxiliary layer is an inclined-surface structure or a right-angled trapezoid structure.

17. The display panel according to claim 13, wherein the auxiliary layer is a stepped structure, and the stepped structure comprises a one-step stepped structure, a two-step stepped structure, or a multi-step stepped structure.

18. The display panel according to claim 17, wherein the auxiliary layer is the one-step stepped structure, a height of the auxiliary layer on a side close to a corresponding one of conductive isolation structures is equal to a height of the auxiliary layer on a side away from a corresponding one of conductive isolation structures.

19. The display panel according to claim 17, wherein the auxiliary layer is the two-step stepped structure or the multi-step stepped structure, and height of steps of the auxiliary layer on the side close to the corresponding one of conductive isolation structures is successively greater than height of steps of the auxiliary layer on a side away from the corresponding one of conductive isolation structures.

20. The display panel according to claim 13, wherein a height of the auxiliary layer at a position close to the conductive isolation structure is equal to a thickness of the inorganic pixel defining layer.
